(19) United States
(12) Patent Application Publication
(10) Pub. No.: US 2025/0266716 A1
(43) Pub. Date: Aug. 21, 2025

(54) WIRELESS CHARGING RANGEFINDER

(71) Applicant: Asia Optical Co., Inc., Taichung (TW)

(72) Inventors: Chun-Guang Zhang, ShenZhen City (CN); Han Lu, ShenZhen City (CN); Hua-Tang Liu, Taichung (TW); Sheng Luo, ShenZhen City (CN); Yin-Liang Liao, Taichung (TW); Yu-Hui Hsu, Taichung (TW)

(21) Appl. No.: 19/007,717

(22) Filed: Jan. 2, 2025

(30) Foreign Application Priority Data
Feb. 21, 2024 (CN) 202410195562.X

(51) Int. Cl. H02J 50/10; G01C 3/02; G01R 31/382; H02J 7/00; H02J 50/90

(52) U.S. Cl. CPC H02J 50/10; G01C 3/02; G01R 31/382; H02J 7/00034; H02J 7/0048; H02J 50/90

(57) ABSTRACT

A wireless charging rangefinder includes at least one rangefinder body and a magnetic unit. The rangefinder body includes a distance measuring unit, a first control unit, a first power source, a first coil, an objective lens unit, and an eyepiece unit, wherein the distance measuring unit, the first power source and the first coil are electrically connected to the first control unit, and an optical axis is configured to pass through the objective lens unit and the eyepiece unit. The magnetic unit is placed with the first coil corresponding to a second coil of a charging device so that the charging device can charge the rangefinder body.

### BACKGROUND OF THE INVENTION

### Field of the Invention

The invention relates to a technical field of a rangefinder device, and more particularly to a wireless charging rangefinder.

### Description of the Related Art

Current optical distance measuring devices have a wide range of applications in the field of, for example, engineering, measurement and even leisure sports. Golf requires measurement of the distance between the hitting point and the fairway, or between the hitting point and the green (or hole), in order to decide which golf club (woods or irons of different specifications) is used for hitting the ball. In addition to the traditional calculations assisted by assistants (club brothers), laser rangefinders have also been widely used by golf enthusiasts in recent years to directly measure the distance.

Laser rangefinders may run out of power after multiple uses and need to be recharged (or need replacement of batteries) so that they can continue to be used. However, the golf course is an outdoor venue. There are no charging facilities. Therefore, users need to carry extra batteries, which is very inconvenient.

### BRIEF SUMMARY OF THE INVENTION

The invention provides a wireless charging rangefinder that allows a mobile charging device to wirelessly charge the rangefinder body, thereby solving the inconvenience problem of the prior art that require users to carry extra batteries.

The wireless charging rangefinder in accordance with an exemplary embodiment of the invention includes at least one rangefinder body and a magnetic unit. The at least one rangefinder body includes a distance measuring unit, a first control unit, a first power source, a first coil, an objective lens unit, and an eyepiece unit, wherein the distance measuring unit, the first power source and the first coil are electrically connected to the first control unit, and an optical axis is configured to pass through the objective lens unit and the eyepiece unit. The magnetic unit is placed with the first coil corresponding to a second coil of a charging device so that the charging device can charge the at least one rangefinder body. The at least one rangefinder body further includes a first housing, the first housing includes a first wall, and the first coil is disposed on the first wall. The charging device further includes a second housing, the second housing includes a second wall, and the second coil is disposed on the second wall.

In another exemplary embodiment, the wireless charging rangefinder includes at least one rangefinder body and a magnetic unit. The at least one rangefinder body includes a distance measuring unit, a first control unit, a first power source, a first coil, an objective lens unit, and an eyepiece unit, wherein the distance measuring unit, the first power source and the first coil are electrically connected to the first control unit, and an optical axis is configured to pass through the objective lens unit and the eyepiece unit. The magnetic unit is placed with the first coil corresponding to a second coil of a charging device so that the charging device can charge the at least one rangefinder body. The charging device includes a second control unit and a second power source. The at least one rangefinder body further includes a state-of-charge detection unit electrically connected to the first control unit. The state-of-charge detection unit is configured to detect a remaining capacity available in the first power source. The first control unit generates a control signal when the remaining capacity reaches a set value. The at least one rangefinder body further includes a rangefinder communication unit electrically connected to the first control unit. The charging device further includes a charging device communication unit electrically connected to the second control unit. The charging device communication unit and the rangefinder communication unit are configured to form a signal connection. The second control unit stops the second power source from supplying power to the second coil, when the second control unit receives the control signal from the first control unit through the rangefinder communication unit and the charging device communication unit.

In yet another exemplary embodiment, the charging device includes a second control unit and a second power source, and the second power source and the second coil are electrically connected to the second control unit. The second power source is configured to generate an electric current that is passed through the second coil. Through an electromagnetic coupling effect between the second coil and the first coil, another electric current is generated and passed through the first coil as so to charge the first power source.

In another exemplary embodiment, the magnetic unit includes a first magnetic element and a second magnetic element attracting each other so as to connect the first wall of the at least one rangefinder body and the second wall of the charging device. The first magnetic element is disposed on the first wall of the first housing or a side wall of the first housing opposite to the first wall. The second magnetic element is disposed on the second wall of the second housing or a side wall of the second housing opposite to the second wall.

In yet another exemplary embodiment, the first wall has a largest area in the first housing.

In another exemplary embodiment, a normal line of the first wall is skewed or intersects with the optical axis.

In yet another exemplary embodiment, the at least one rangefinder body further includes an image stabilization unit electrically connected to the first control unit. The image stabilization unit is coupled to the distance measuring unit for keep the distance measuring unit in a predetermined measurement position when the at least one rangefinder body shakes.

In another exemplary embodiment, the charging device further includes a location information generation unit electrically connected to the second control unit. The location generation unit is configured to receive a satellite signal so as to generate location data. The charging device further includes a charging device communication unit electrically connected to the second control unit. The charging device communication unit is configured to form a signal connection with an electronic device. The location data is transmitted to the electronic device through the charging device communication unit. The charging device further includes a display unit electrically connected to the second control unit.

In yet another exemplary embodiment, the charging device or the at least one rangefinder body further includes a plurality of environment sensors that include a temperature sensor, a humidity sensor, and a wind direction sensor.

In another exemplary embodiment, the charging device further includes a power management module and a charging interface electrically connected to the power management module. The power management module is electrically connected to the second control unit. The charging interface is connected to an external power source. The second power source is charged by the external power source through the power management module.

In yet another exemplary embodiment, the at least one rangefinder body is plural, charged by the charging device.

In the wireless charging rangefinder of the invention, the rangefinder body is provided with a first coil and the charging device is provided with a second coil. Through the electromagnetic coupling effect between the second coil and the first coil, the second power source of the charging device transmits power to the first power source of the rangefinder body so as to charge the first power source. The invention provides a fast, portable and efficient wireless charging technique without requirement of disassembling the battery, providing long-lasting and reliable power for the rangefinder, extending battery life and reducing battery pollution. Further, the invention externally expands practical functions that require large power consumption, enriches their functions, and increases the interactivity of the rangefinder.

### BRIEF DESCRIPTION OF THE DRAWINGS

FIG. 1 is system block diagram of a wireless charging rangefinder in accordance with an embodiment of the invention.

FIG. 2 is perspective view of a wireless charging rangefinder in accordance with an embodiment of the invention.

FIG. 3 depicts the wireless charging rangefinder of FIG. 2 in use.

FIG. 4 is a perspective view of the rangefinder body of the wireless charging rangefinder of FIG. 2.

FIG. 5 is a perspective view of the charging device of the wireless charging rangefinder of FIG. 2.

FIG. 6 is a perspective view of the charging device of FIG. 5, with a part thereof removed.

FIG. 7 is a schematic view showing a communication connection between the wireless charging rangefinder and a mobile phone.

FIG. 8 is a schematic view showing multiple rangefinder bodies of the invention wirelessly charged by a charging device.

### DETAILED DESCRIPTION OF THE INVENTION

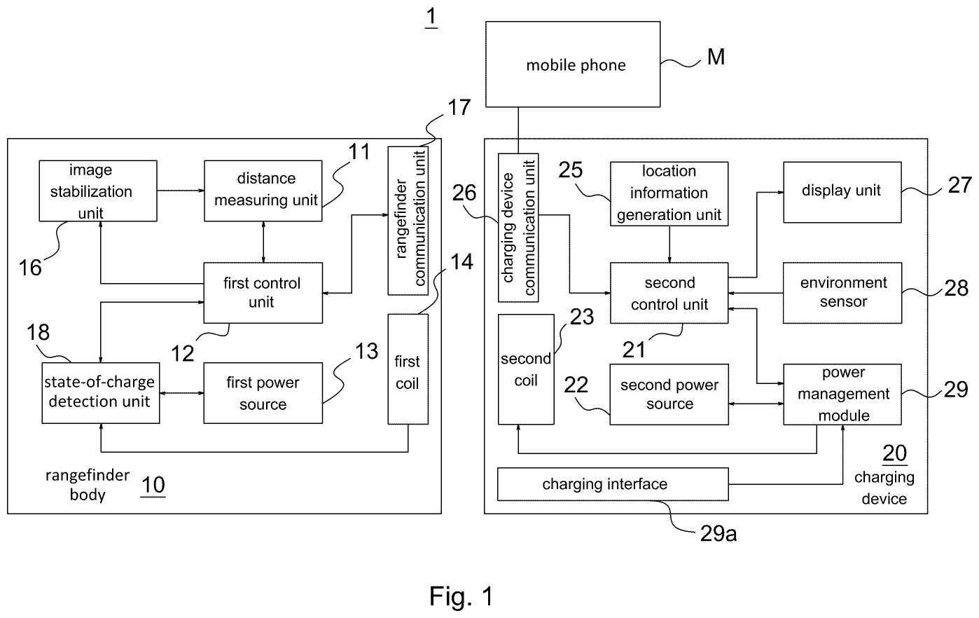

Referring to FIGS. 1, 2, 3 and 4, a rangefinder 1 with wireless charging function in accordance with an embodiment of the invention includes at least one rangefinder body 10, a charging device 20 and a magnetic unit 30.

The rangefinder body 10 includes a distance measuring unit 11, a first control unit 12, a power source 13, a first coil 14, a first housing 15, an objective lens unit 10a and an eyepiece unit 10b. The distance measuring unit 11, the first control unit 12, the power source 13 and the first coil 14 are disposed in the first housing 15 and are electrically connected to the first control unit 12. An optical axis O is configured to pass through the objective lens unit 10a and the eyepiece unit 10b. The distance measuring unit 11 includes a light source (not shown), a beam projecting lens (not shown), a beam receiving lens (not shown) and a sensor (not shown), thereby capable of measuring a distance. In this embodiment, the first control unit 12 is a microprocessor and the first power source 13 is a lithium battery. The first control unit 12 and the first coil 14 are disposed on a circuit board (not shown). The first power source 13 supplies power to the distance measuring unit 11 and the first control unit 12 so that the user can measure the distance with the distance measuring unit 11.

The charging device 20 includes a second control unit 21, a second power source 22, a second coil 23 and a second housing 24. The second control unit 21, the second power source 22, the second coil 23 are disposed in the second housing 24. The second power source 22 and the second coil 23 are electrically connected to the second control unit 21. In this embodiment, the second control unit 21 is a microprocessor or a single chip, and the second power source 22 is a lithium battery. The second control unit 21 and the second coil 23 are disposed on a circuit board (not shown).

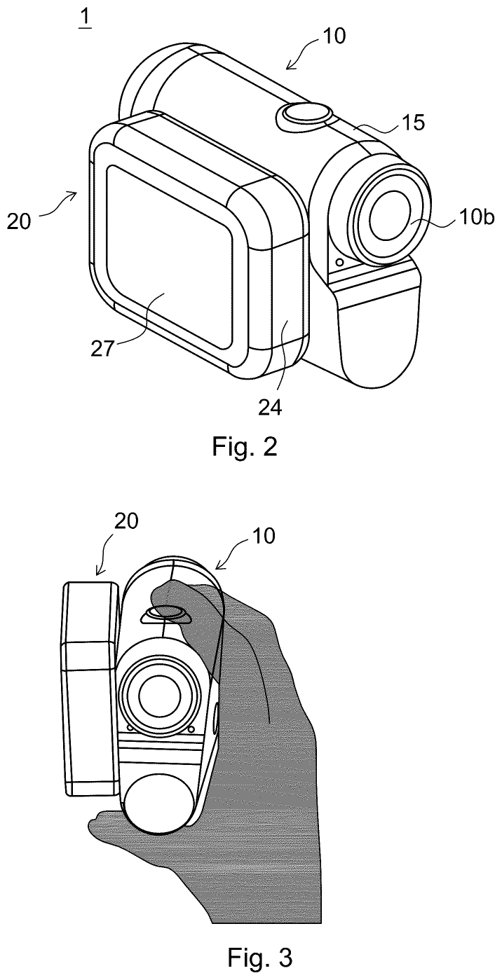

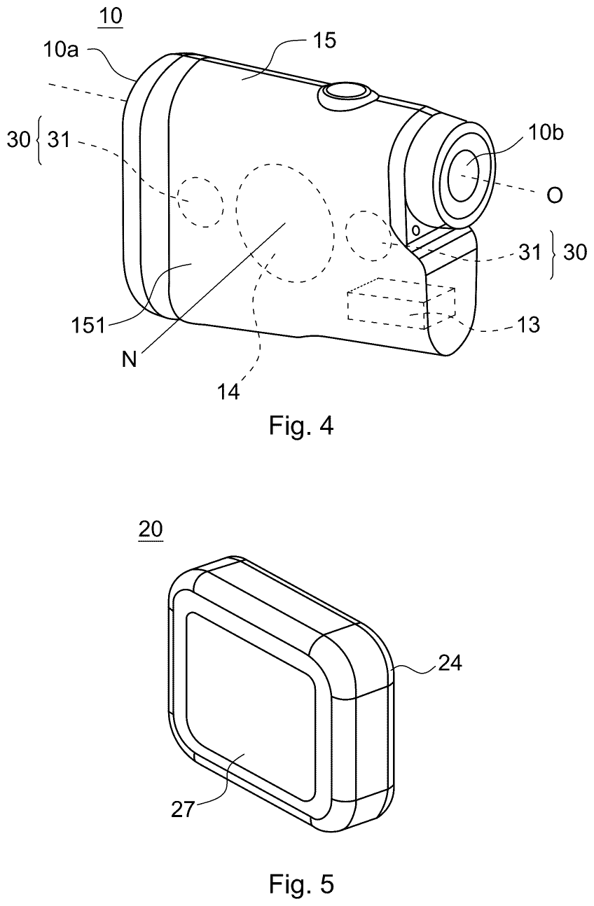

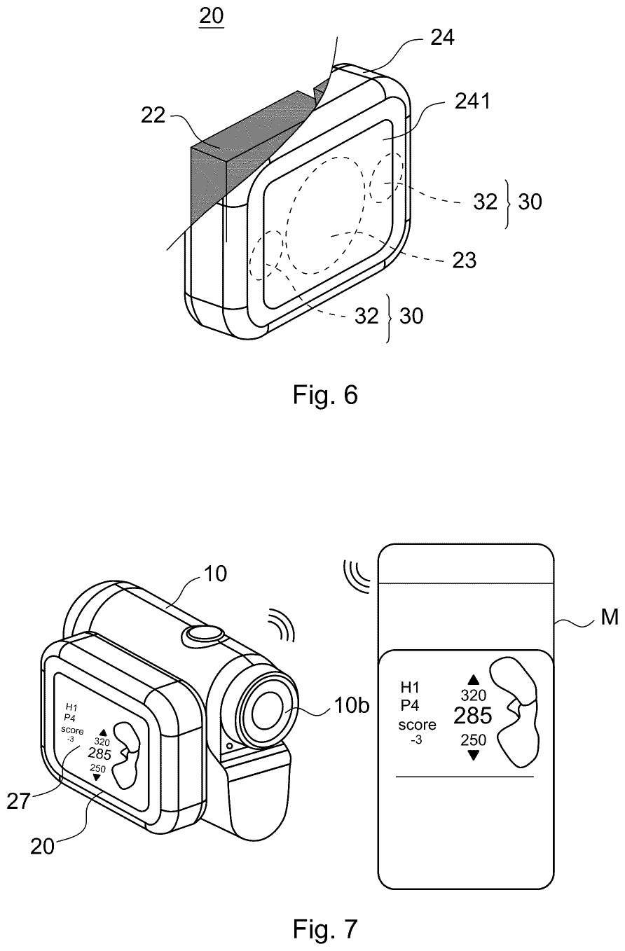

The magnetic unit 30 (shown in FIGS. 4 and 6) is provided for connecting the rangefinder body 10 and the charging device 20 as shown in FIG. 2. In this embodiment, the magnetic unit 30 includes a first magnetic element 31 and a second magnetic element 32. The first magnetic element 31 is disposed on the inner surface of a first wall 151 of a first housing 15 of the rangefinder body 10. The second magnetic element 32 is disposed on the inner surface of a second wall 241 of a second housing 24 of the charging device 20. The user places the first wall 151 of the first housing 15 and the second wall 241 of the second housing 24 to face each other, and the first magnetic element 31 and the second magnetic element 32 attract each other to connect the charging device 20 and the rangefinder body 10. The first wall 151 is the wall with the largest surface area of the first housing 15 so that it has enough area for installation of the charging device thereby increasing the stability of installation. The first wall 151 has a normal line N that is skewed or intersects with the optical axis O. In this embodiment, the normal line N of the first wall 151 is skewed with the optical axis O. In some other embodiments, the normal line N of the first wall 151 intersects with or even is orthogonal to the optical axis O.

The first coil 14 is disposed on the inner surface of the first wall 151. The second coil 23 is disposed on the inner surface of the second wall 241. When the first magnetic element 31 and the second magnetic element 32 attract each other, the first wall 151 is abutted against the second wall 241, with the first coil 14 corresponded to the second coil 23. The electric current of the second power source 22 is passed through the second coil 23 to generate a magnetic field. Through the electromagnetic coupling effect between the second coil 23 and the first coil 14, the magnetic field generates an electric current in the first coil 14 to charge the first power source 13.

In this embodiment, the first coil 14 and the first magnetic element 31 are disposed on the first wall 151 so that the first coil 14 and the second coil 23 correspond to each other and are electromagnetically coupled. However, the invention is not limited thereto. In another embodiment, the first magnetic element 31 may be disposed on a side wall opposite to the first wall 151. In such an arrangement, the magnetic field of the first magnetic element 31 can still pass through the rangefinder body 10 and can interact with the second magnetic element 32 to produce magnetic attraction if the magnetic flux density of the first magnetic element 31 is enhanced (the second magnetic element 32 is disposed on the second wall 241 of the second housing 24 of the charging device 20). Such an arrangement can also achieve the function of connecting the charging device 20 to the rangefinder body 10. In yet another embodiment, the second magnetic element 32 may be disposed on a side wall opposite to the second wall 241 to achieve the same function.

In this embodiment, the charging device 20 is connected to the rangefinder body 10 with magnetic attraction mechanism. However, the invention is not limited thereto. In some other embodiments, the charging device 20 can be connected to the rangefinder body 10 with engaging mechanism or buckle mechanism, with the first wall 151 placed corresponding to the second wall 241.

As shown in FIG. 1, the rangefinder body 10 of this embodiment further includes an image stabilization unit 16. The image stabilization unit 16 is electrically connected to the first control unit 12. Further, the image stabilization unit 16 is coupled to the distance measuring unit 11, for keep the distance measuring unit 11 in a predetermined measurement position when the rangefinder body 10 shakes. The image stabilization unit 16 includes a coil, a magnet and a magnetic induction element (for example, Hall sensor). The coil and the magnet are coupled to achieve position compensation, and the magnetic induction element detects the position of the magnet and feeds a position detection result back to the second control unit 12.

When the magnetic induction element (Hall sensor) of the image stabilization device of the prior art is too close to the first magnetic element 31, it may affect the magnetic induction element (Hall sensor). Specifically, it may affect the distance measuring unit and cause the optical axis to deviate because of the magnetic attraction. In other words, the magnetic attraction mechanism of the prior art cannot be used along with the image stabilization device. In the magnetic unit 30 of this embodiment, the distance between the first magnetic element 31 and the magnetic induction element (Hall sensor) is well arranged, or the magnetic induction element (Hall sensor) under the magnetic action of the first magnetic element 31 is well adjusted, so that the image stabilization unit 16 can still normally function to compensate for hand-held vibrations despite magnetic interference.

As shown in FIGS. 1, 5 and 6, the charging device 20 further includes a location information generation unit 25, a charging device communication unit 26, a display unit 27 and an environment sensor 28. The location information generation unit 25, the charging device communication unit 26, the display unit 27 and the environment sensor 28 are electrically connected to the second control unit 21. The location information generation unit 25 is configured to receive the satellite signal so as to generate location data. For example, the location information generation unit 25 can be a satellite positioning chip module, which receives signals from, for example, the American Global Positioning System (GPS) or China's BeiDou Navigation Satellite System to generate location coordinate data, and then cooperates with, for example, a map of a golf course so that the user can know the current location. The charging device communication unit 26 is configured to form a signal connection with the rangefinder body 10 or an external electronic device. As shown in FIG. 7, the charging device 20 is configured to form an electrical connection with a mobile phone M. Multiple environment sensors 28 are configured to sense the environment. Specifically, the environment sensors 28 include a temperature sensor, a humidity sensor, and a wind direction sensor for generating environmental data for such as temperature, humidity, and wind direction. The location coordinate data and environmental data (such as data for temperature, humidity, and wind direction) can be displayed by the display unit 27 or transmitted to the mobile phone M through the charging device communication unit 26 to be displayed by the mobile phone M. The display unit 27 may be a touch screen that allows input of setting data by the user in addition to display of information (in FIG. 7, symbol H1 means hole 1, and symbol P4 means par 4).

The charging device 20 further includes a power management module 29 and a charging interface 29a. The charging interface 29a is disposed on the second housing 24 and electrically connected to the power management module 29. The power management module 29 is a charging circuit electrically connected to the second control unit 21. The power management module 29 is configured to detect the remaining capacity available in the second power source 22 for generating remaining capacity data that are displayed by the display unit 27. The charging interface 29a has a socket electrical connector (e.g. USB Type-C electrical connector) connected to an external power source (e.g mains electricity) via a cable. The power from the external power source is transmitted to the power management module 29 through the charging interface 29a to charge the second power source 22.

The rangefinder body 10 further includes a rangefinder communication unit 17 and a state-of-charge detection unit 18. The rangefinder communication unit 17 and the state-of-charge detection unit 18 are electrically connected to the first control unit 12. The state-of-charge detection unit 18 is configured to detect the remaining capacity available in the first power source 13 for generating the remaining capacity data. The first control unit 12 compares the remaining capacity data with a set value. When the remaining capacity data of the first power source 13 reach the set value, the first control unit 12 generates a control signal. The rangefinder communication unit 17 is configured to form a signal connection with the charging device communication unit 26. The control signal is transmitted to the second control unit 21 through the rangefinder communication unit 17 and the charging device communication unit 26. The second control unit 21 is able to stop the second power source 22 from supplying power to the second coil 23. For example, when detecting that the remaining capacity of the first power source 13 reaches 100%, the state-of-charge detection unit 18 generates a control signal in three seconds. The remaining capacity data generated by the state-of-charge detection unit 18 may also be transmitted to the second control unit 21 through the rangefinder communication unit 17, and further to the display unit 27 for displaying the remaining capacity of the first power source 13. The rangefinder communication unit 17 and the charging device communication unit 26 may be, for example, Bluetooth communication chips (or circuits) or WiFi communication chips (or circuits).

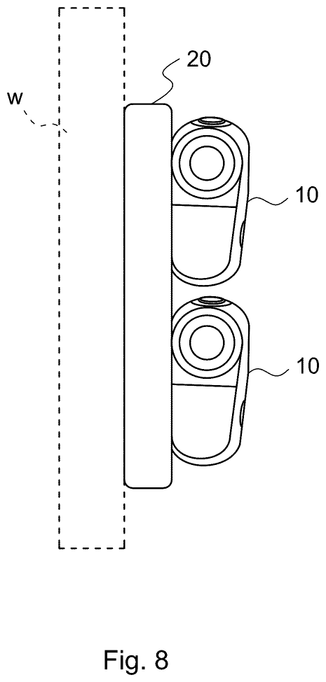

As shown in FIG. 8, in another embodiment, a charging device 20 is configured to charge a plurality of rangefinder bodies 10. The charging device 20 may be installed on a golf cart W to have a larger second housing 24 and to have multiple second coils. When charging is required, multiple rangefinder bodies 10 are coupled to the charging device 20 with a magnetic attraction structure and disposed corresponding to the multiple second coils so as to be charged.

In the wireless charging rangefinder of the invention, the rangefinder body is provided with a first coil and the charging device is provided with a second coil. Through the electromagnetic coupling effect between the second coil and the first coil, the second power source of the charging device transmits power to the first power source of the rangefinder body so as to charge the first power source. The invention provides a fast, portable and efficient wireless charging technique without requirement of disassembling the battery, providing long-lasting and reliable power for the rangefinder, extending battery life and reducing battery pollution. Further, the invention externally expands practical functions that require large power consumption, enriches their functions, and increases the interactivity of the rangefinder, wherein the practical functions that require large power consumption include, for example but not limited to, using the location information generation unit 25 to receive satellite signals to generate location data, using the charging device communication unit 26 to form a signal connection with the electronic device, and transmitting the location data to the electronic device through the charging device communication unit 26 or multiple environment sensors 28. In another embodiment, the location information generation unit 25 and the environment sensor 28 may be disposed in the rangefinder body 10, or the rangefinder communication unit 17 is configured to form a signal connection with the charging device 20 or an external electrical device (e.g. the rangefinder body 10 is configured to form an electrical connection with the mobile phone M). Since the operations are relatively power-consuming, the aforementioned relatively power-consuming functions are activated only when the charging device 20 charges the rangefinder body 10.

What is described above is only the preferred embodiment of the invention, and the scope of the invention is not limited thereto. That is, the simple equivalent changes and modifications made according to the description of the invention and the claims are all within the scope of the invention. Further, any one of the embodiments or claims is not required to achieve all the objects or advantages or features of the invention. Further, the abstract and title are only used to assist in the search of patent documents and are not intended to limit the scope of the invention. Further, the terms “first” and “second” described in the specification and claims are only used to distinguish between different elements, embodiments or scopes, without limiting the quantity of the elements with an upper limit or a lower limit.

What is claimed is:

1. A wireless charging rangefinder, comprising:
at least one rangefinder body comprising a distance measuring unit, a first control unit, a first power source, a first coil, an objective lens unit, and an eyepiece unit, wherein the distance measuring unit, the first power source and the first coil are electrically connected to the first control unit, and an optical axis is configured to pass through the objective lens unit and the eyepiece unit;
a magnetic unit placed with the first coil corresponding to a second coil of a charging device so that the charging device can charge the at least one rangefinder body;
wherein the at least one rangefinder body further comprises a first housing, the first housing comprises a first wall, and the first coil is disposed on the first wall;
wherein the charging device further comprises a second housing, the second housing comprises a second wall, and the second coil is disposed on the second wall.

2. The wireless charging rangefinder as claimed in claim 1, wherein:
the charging device comprises a second control unit and a second power source, and the second power source and the second coil are electrically connected to the second control unit;
the second power source is configured to generate an electric current that is passed through the second coil;
through an electromagnetic coupling effect between the second coil and the first coil, another electric current is generated and passed through the first coil as so to charge the first power source.

3. The wireless charging rangefinder as claimed in claim 1, wherein:
the magnetic unit comprises a first magnetic element and a second magnetic element attracting each other so as to connect the first wall of the at least one rangefinder body and the second wall of the charging device;
the first magnetic element is disposed on the first wall of the first housing or a side wall of the first housing opposite to the first wall;
the second magnetic element is disposed on the second wall of the second housing or a side wall of the second housing opposite to the second wall.

4. The wireless charging rangefinder as claimed in claim 1, wherein the first wall has a largest area in the first housing.

5. The wireless charging rangefinder as claimed in claim 1, wherein a normal line of the first wall is skewed or intersects with the optical axis.

6. The wireless charging rangefinder as claimed in claim 1, wherein:
the at least one rangefinder body further comprises an image stabilization unit electrically connected to the first control unit;
the image stabilization unit is coupled to the distance measuring unit for keep the distance measuring unit in a predetermined measurement position when the at least one rangefinder body shakes.

7. The wireless charging rangefinder as claimed in claim 2, wherein:
the charging device further comprises a location information generation unit electrically connected to the second control unit;
the location generation unit is configured to receive a satellite signal so as to generate location data;
the charging device further comprises a charging device communication unit electrically connected to the second control unit;
the charging device communication unit is configured to form a signal connection with an electronic device;
the location data is transmitted to the electronic device through the charging device communication unit;
the charging device further comprises a display unit electrically connected to the second control unit.

8. The wireless charging rangefinder as claimed in claim 1, wherein the charging device or the at least one rangefinder body further comprises a plurality of environment sensors that comprise a temperature sensor, a humidity sensor, and a wind direction sensor.

9. The wireless charging rangefinder as claimed in claim 2, wherein:
the charging device further comprises a power management module and a charging interface electrically connected to the power management module;
the power management module is electrically connected to the second control unit;
the charging interface is connected to an external power source;
the second power source is charged by the external power source through the power management module.

10. The wireless charging rangefinder as claimed in claim 1, wherein the at least one rangefinder body is plural, charged by the charging device.

11. A wireless charging rangefinder, comprising:
at least one rangefinder body comprising a distance measuring unit, a first control unit, a first power source, a first coil, an objective lens unit, and an eyepiece unit, wherein the distance measuring unit, the first power source and the first coil are electrically connected to the first control unit, and an optical axis is configured to pass through the objective lens unit and the eyepiece unit;
a magnetic unit placed with the first coil corresponding to a second coil of a charging device so that the charging device can charge the at least one 9 rangefinder body;
wherein the charging device comprises a second control unit and a second power source;
wherein the at least one rangefinder body further comprises a state-of-charge detection unit electrically connected to the first control unit;
wherein the state-of-charge detection unit is configured to detect a remaining capacity available in the first power source;
wherein the first control unit generates a control signal when the remaining capacity reaches a set value;
wherein the at least one rangefinder body further comprises a rangefinder communication unit electrically connected to the first control unit;
wherein the charging device further comprises a charging device communication unit electrically connected to the second control unit;
wherein the charging device communication unit and the rangefinder communication unit are configured to form a signal connection;
wherein the second control unit stops the second power source from supplying power to the second coil, when the second control unit receives the control signal from the first control unit through the rangefinder communication unit and the charging device communication unit.

12. The wireless charging rangefinder as claimed in claim 11, wherein:
the charging device comprises a second control unit and a second power source, and the second power source and the second coil are electrically connected to the second control unit;
the second power source is configured to generate an electric current that is passed through the second coil;
through an electromagnetic coupling effect between the second coil and the first coil, another electric current is generated and passed through the first coil as so to charge the first power source.

13. The wireless charging rangefinder as claimed in claim 11, wherein:
the magnetic unit comprises a first magnetic element and a second magnetic element attracting each other so as to connect the first wall of the at least one rangefinder body and the second wall of the charging device;
the first magnetic element is disposed on the first wall of the first housing or a side wall of the first housing opposite to the first wall;
the second magnetic element is disposed on the second wall of the second housing or a side wall of the second housing opposite to the second wall.

14. The wireless charging rangefinder as claimed in claim 11, wherein the first wall has a largest area in the first housing.

15. The wireless charging rangefinder as claimed in claim 11, wherein a normal line of the first wall is skewed or intersects with the optical axis.

16. The wireless charging rangefinder as claimed in claim 11, wherein:
the at least one rangefinder body further comprises an image stabilization unit electrically connected to the first control unit;
the image stabilization unit is coupled to the distance measuring unit for keep the distance measuring unit in a predetermined measurement position when the at least one rangefinder body shakes.

17. The wireless charging rangefinder as claimed in claim 12, wherein:
the charging device further comprises a location information generation unit electrically connected to the second control unit;
the location generation unit is configured to receive a satellite signal so as to generate location data;
the charging device further comprises a charging device communication unit electrically connected to the second control unit;
the charging device communication unit is configured to form a signal connection with an electronic device;
the location data is transmitted to the electronic device through the charging device communication unit;
the charging device further comprises a display unit electrically connected to the second control unit.

18. The wireless charging rangefinder as claimed in claim 11, wherein the charging device or the at least one rangefinder body further comprises a plurality of environment sensors that comprise a temperature sensor, a humidity sensor, and a wind direction sensor.

19. The wireless charging rangefinder as claimed in claim 12, wherein:
the charging device further comprises a power management module and a charging interface electrically connected to the power management module;
the power management module is electrically connected to the second control unit;
the charging interface is connected to an external power source;
the second power source is charged by the external power source through the power management module.

20. The wireless charging rangefinder as claimed in claim 11, wherein the at least one rangefinder body is plural, charged by the charging device.
